(19) United States
(12) Patent Application Publication
(10) Pub. No.: US 2014/0331006 A1
(43) Pub. Date: Nov. 6, 2014

(54) SEMICONDUCTOR MEMORY DEVICES

(71) Applicant: Samsung Electronics Co., Ltd., Suwon-Si (KR)

(72) Inventors: Hoi-Ju CHUNG, Yongin-si (KR); Chul-Sung PARK, Seoul (KR); Tae-Seong JANG, Yongin-si (KR); Gong-Heum HAN, Hwaseong-si (KR); Jang-Woo RYU, Seoul (KR)

(73) Assignee: Samsung Electronics Co., Ltd., Suwon-Si (KR)

(21) Appl. No.: 14/208,339

(22) Filed: Mar. 13, 2014

Related U.S. Application Data
(60) Provisional application No. 61/819,734, filed on May 6, 2013.

(30) Foreign Application Priority Data
Jul. 16, 2013 (KR) 10-2013-0083251

(51) Int. Cl. G11C 7/10

(52) U.S. Cl. CPC G11C 7/1096; G11C 7/1072
USPC 711/105

(57) ABSTRACT

A semiconductor memory device includes a memory cell array, a data inversion/mask interface and a write circuit. The data inversion/mask interface receives a data block including a plurality of unit data, each of the plurality of unit data having a first data size, and the data inversion/mask interface selectively enables each data mask signal associated with each of the plurality of unit data based on a number of first data bits in a second data size of each unit data. The second data size is smaller than a first data size of the unit data. The write circuit receives the data block and performs a masked write operation that selectively writes each of the plurality of unit data in the memory cell array in response to the data mask signal.

### CROSS-REFERENCE TO RELATED APPLICATION

This U.S. non-provisional application claims the benefit of priority under 35 U.S.C. §119 to U.S. Provisional Application No. 61/819,734 filed on May 6, 2013 in the USPTO and to Korean Patent Application No. 10-2013-0083251, filed on Jul. 16, 2013, in the Korean Intellectual Property Office (KIPO), the contents of which are incorporated herein in their entirety by reference.

### BACKGROUND

1. Technical Field

Example embodiments relate generally to semiconductor devices, and more particularly, to semiconductor memory devices and/or memory systems including the same.

2. Discussion of the Related Art

In a memory system including conventional semiconductor memory devices, a data inversion scheme is used for reducing power consumption when a memory controller transmits data to the semiconductor memory device. The memory controller also transmits a data mask signal to the semiconductor memory device through separate pins. Therefore, the number of pins increases.

### SUMMARY

In accordance with some example embodiments of the inventive concepts, semiconductor memory devices capable of reducing a number of pins are provided.

In accordance with some example embodiments of the inventive concepts, memory systems including the semiconductor memory devices are provided.

According to an example embodiment, a semiconductor memory device includes a memory cell array, a data inversion/mask interface and a write circuit. The data inversion/mask interface receives a data block including a plurality of unit data, each of the plurality of unit data having a first data size, and the data inversion/mask interface selectively enables each data mask signal associated with each of the plurality of unit data based on a number of data bits having a first logic level in a portion of each the plurality of unit data, the portion having a second data size. The second data size is smaller than the first data size. The write circuit receives the data block and performs masked write operation that selectively writes each unit data in the memory cell array in response to the data mask signal.

In some example embodiments, the second data size may be greater than half of the first data size.

The first data size may correspond to a size of one byte, and the second data size may correspond to a value which is greater than half of the first data size by two.

In some example embodiments, the data inversion/mask interface may be configured to enable the data mask signal when the number of data bits having the first logic level in the portion of each of the plurality of unit data is equal to or greater than a reference value.

When the first data size is eight, the reference value may be five.

In some example embodiments, the first logic level may be one of data ‘1’ and data ‘0’.

In some example embodiments, the data inversion/mask interface may include a data masking decision circuit that is configured to enable the data mask signal when the number of data bits having the first logic level is equal to or greater than a reference value, the reference value being greater than half of the first data size, and a data inversion circuit that is configured to selectively inverts data bits of each of the plurality of unit data in response to a flag signal and provides input data to the write circuit.

The write circuit may be configured to perform a masked write operation that does not write corresponding unit data of the input data to the memory cell array when the data mask signal is enabled, and the write circuit may be configured to perform a data write operation that writes corresponding unit data of the input data to the memory cell array when the data mask signal is disabled.

The flag signal may indicate whether data bits of a corresponding one of the plurality of unit data are inverted or not.

The data masking decision circuit may include a first operation circuit that is configured to operate on less significant data bits of the plurality of unit data to generate first output signals having a pattern according to a number of data bits having the first logic level in the less significant data bits, a second operation circuit that is configured to operate on more significant data bits of the plurality of unit data to generate second output signals having a pattern according to a number of data bits having the first logic level in the more significant data bits, and a data mask signal output circuit that configured to provide the data mask signal based on the first output signals and the second output signals.

The data masking decision circuit may include a first operation circuit that configured to operate on less significant data bits of rest data bits to generate first output signals according to the number of data bits having the first logic level in the less significant data bits, the rest data bits obtained by omitting at least two upper data bits from the plurality of unit data, a second operation circuit that is configured to operate on more significant data bits of the rest data bits to generate second output signals according to the number of data bits having the first logic level in the more significant data bits, and a data mask signal output circuit that configured to provide the data mask signal based on the first output signals and the second output signals.

According to an example embodiment, a memory system includes a semiconductor memory device and a memory controller. The semiconductor memory device is configured to perform a masked write operation according to a number of data bits having a first logic level in each of a plurality of unit data. The memory controller controls the semiconductor memory device. The memory controller is configured to provide a write data block including the plurality of unit data to the semiconductor memory device. The memory controller includes a memory interface that is configured to selectively convert some data bits having a second logic level to data bits having the first logic level in each of the plurality of unit data such that the number of data bits having the first logic level in each of the plurality of unit data is equal to or greater than a reference value, the reference value being greater than half of data size of each of the plurality of unit data.

In some example embodiments, the memory interface may include a data inversion circuit that is configured to selectively invert each unit data to provide first output data and generates a flag signal indicating whether each of the plurality of unit data is inverted or not, and a bit converting circuit that is configured to selectively convert some data bits having the second logic level to the data bits having the first logic level in the first output data to provide second output data in response to a mask information signal, the mask information signal indicating whether masking masked write operation is performed or not.

The bit converting circuit may convert some data bits having the second logic level to the data bits having the first logic level in the first output data such that a number of the first data bits in rest data bits is equal to or greater than the reference value when the mask information signal indicates that the masked write operation is to be performed. The rest data bits may be obtained by omitting at least two data bits from more significant data bits of the first output data.

In some example embodiments, the semiconductor memory device may include a data inversion/mask interface that is configured to receive the write data block and configured to selectively enable a data mask signal associated with each of the plurality of unit data having a first data size, based on the number of data bits having the first logic level in a second data size of each of the plurality of unit data. The second data size may be smaller than the first data size.

According to an example embodiment, a memory system includes a memory controller configured to provide a write data block. The memory controller includes a data inversion circuit configured to provide an output data block by selectively inverting each unit data of an input data block based on a number of data bits having a first logic level in each unit data of the input data block. The memory controller also includes a bit converting circuit configured to selectively convert some data bits having a second logic level to data bits having the first logic level in each unit data of the output data block to produce the write data block. The data inversion circuit selectively converts the output data block in response to a mask information signal such that the number of the data bits having the first logic level in each unit data of the write data block is equal to or greater than a reference value. The memory system also includes a semiconductor memory device configured to perform one of a masked write operation and a write operation based on the number of data bits having the first logic level in the write data block.

In some example embodiments, the reference value may be greater than half of data size of each unit data of the output data block and is smaller than a data size of each unit data of the output data block.

In some example embodiments, the data inversion circuit may further be configured to provide a flag signal indicating whether corresponding unit data of the write data block is inverted or not.

In some example embodiments, the data inversion circuit may be configured to count a number of bit changes between a unit data of the write data block and a unit data of a previous write data block immediately preceding the write data block, and is configured to selectively invert data bits of the unit data of the write data block based on the number of bit changes.

In some example embodiments, the bit converting circuit may be configured to selectively convert two data bits having the second logic level to data bits having the first logic level in the unit data of the output data block when the mask information is one of a high logic level and a low logic level.

Accordingly, a memory controller converting at least two data bits having a first logic level to each unit data, which is to be provided to a semiconductor memory device, when data masking operation is to be performed. Thus, the semiconductor memory device may selectively perform one of the data masking operation, which does not write (e.g., masks writing) corresponding unit data to the memory cell array when the number of the first data bits in unit data of data from the memory controller is equal to or greater than a reference value, and the write operation, which writes the corresponding unit data in the memory cell array when the number of the data bits having the first logic level in the unit data is smaller than the reference value. Therefore, the semiconductor memory device may perform the masked write operation based on the number of data bits having the first logic level without transmitting the data mask signal to each of the semiconductor memory devices through separate pins, and thus the number of required pins may be reduced.

### BRIEF DESCRIPTION OF THE DRAWINGS

Illustrative, non-limiting example embodiments will be more clearly understood from the following detailed description taken in conjunction with the accompanying drawings.

FIG. 1 is a block diagram illustrating an electronic system according to an example embodiment.

FIG. 2 is a block diagram illustrating an example of the memory system in FIG. 1 to an example embodiment.

FIG. 3 is block diagram illustrating a memory controller in FIG. 2 according to an example embodiment.

FIG. 4 illustrates data and signals in the memory controller of FIG. 3.

FIG. 5 is a block diagram illustrating a semiconductor memory device in FIG. 2 according to an example embodiment.

FIG. 6 is a block diagram illustrating the data inversion/mask interface in FIG. 5 according to an example embodiment.

FIG. 7 is a block diagram illustrating an example of the data masking decision circuit in FIG. 6 according to an example embodiment.

FIG. 8 illustrates the first and second operation circuits in FIG. 7 according to an example embodiment.

FIG. 9 is a circuit diagram illustrating one of the unit logics in FIG. 8 according to an example embodiment.

FIG. 10 is circuit diagram illustrating an example of the data mask signal output circuit in FIG. 7 according to an example embodiment.

FIG. 11 is circuit diagram illustrating an example of the data mask signal output circuit in FIG. 7 according to an example embodiment.

FIG. 12 is a block diagram illustrating an example of the data masking decision circuit in FIG. 6 according to an example embodiment.

FIG. 13 illustrates data and signals in the semiconductor memory device of FIG. 5.

FIG. 14 is a block diagram illustrating a memory module including the semiconductor memory device according to an example embodiment.

FIG. 15 is a block diagram illustrating a mobile system according to an example embodiment.

FIG. 16 is a block diagram illustrating a computing system according to an example embodiment.

### DETAILED DESCRIPTION

Various example embodiments will be described more fully hereinafter with reference to the accompanying drawings, in which some example embodiments are shown. The example embodiments may, however, be embodied in many different forms and should not be construed as limited to the example embodiments set forth herein. Rather, these example embodiments are provided so that this disclosure will be thorough and complete, and will fully convey the scope of the example embodiments of the inventive concepts to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concepts. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concepts. As used herein, the singular forms “a,” “an” and “the” are intended to include the plural forms as well, unless the context clearly indicates otherwise. It will be further understood that the terms “includes,” “including”, “comprises” and/or “comprising,” when used in this specification, specify the presence of stated features, operations, elements, and/or components, but do not preclude the presence or addition of one or more other features, operations, elements, components, and/or groups thereof.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments of the present invention will be explained in further detail with reference to the accompanying drawings.

FIG. 1 is a block diagram illustrating an electronic system according to an example embodiment.

Referring to FIG. 1, an electronic system 10 includes a host 20 and a memory system 30. The memory system 30 includes a memory controller 100 and a plurality of semiconductor memory devices 200a˜200n.

The host 20 may communicate with the memory system 30 through various interface protocols, for example, Peripheral Component Interconnect-Express (PCI-E), Advanced Technology Attachment (ATA), Serial ATA (SATA), Parallel ATA (PATA), or serial attached SCSI (SAS). Further, the host 20 may communicate with the memory system 30 through interface protocols, for example, Universal Serial Bus (USB), Multi-Media Card (MMC), Enhanced Small Disk Interface (ESDI), or Integrated Drive Electronics (IDE).

The memory controller 100 controls overall operation of the memory system 30. The memory controller 100 controls overall data exchange between the host 20 and the semiconductor memory devices 200a˜200n. For example, the memory controller 100 may write data in the semiconductor memory devices 200a˜200n and/or may read data from the semiconductor memory devices 200a˜200n in response to request from the host 20.

Further, the memory controller 100 may issue operation commands to the semiconductor memory devices 200a˜200n for controlling the semiconductor memory devices 200a˜200n.

In some example embodiments, each of the semiconductor memory devices 200a˜200n may be a dynamic random access memory (DRAM), for example, a double data rate synchronous dynamic random access memory (DDR SDRAM), a low power double data rate synchronous dynamic random access memory (LPDDR SDRAM), a graphics double data rate synchronous dynamic random access memory (GDDR SDRAM), or a Rambus dynamic random access memory (RDRAM). In some example embodiments, each of the semiconductor memory devices 200a˜200n may be volatile semiconductor memory devices, which may include a refresh operation.

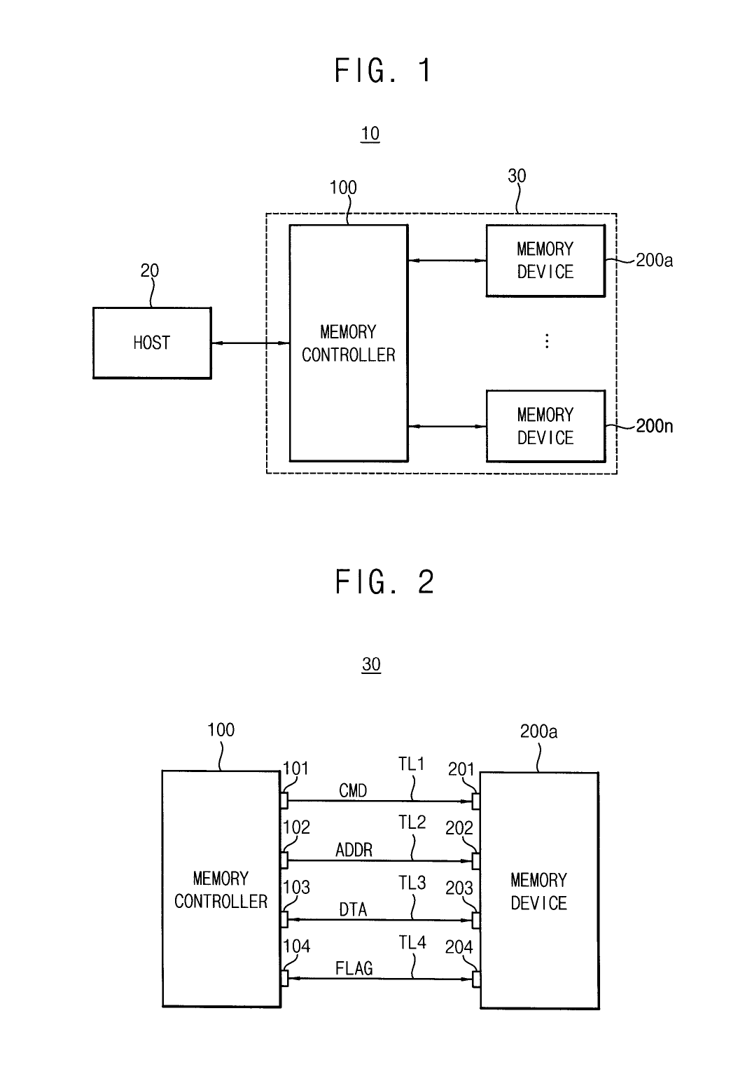

FIG. 2 is a block diagram illustrating an example of the memory system in FIG. 1 to an example embodiment.

In FIG. 2, one semiconductor memory device 200a in communication with the memory controller 100 is illustrated for convenience. However, the details discussed herein related to semiconductor memory device 200a may equally apply to the other semiconductor memory devices 200b˜200n.

Referring to FIG. 2, the memory system 30 includes the memory controller 100 and the semiconductor memory device 200a. Each of the memory controller 100 and the semiconductor memory device 200a may be formed as a single semiconductor chip or as a group of chips (e.g., semiconductor memory device 200a being a stack of semiconductor chips in a semiconductor package). The memory controller 100 and the semiconductor memory device 200a may be connected to each other through corresponding command pins 101 and 201, corresponding address pins 102 and 202, corresponding data pins 103 and 203, and corresponding separate pins 104 and 204. The command pins 101 and 201 transmit a command signal CMD through a command transmission line TL1, the address pins 102 and 202 transmit an address signal ADDR through an address transmission line TL2, the data pins 103 and 203 exchange data block DTA through a data transmission line TL3, and the separate pins 104 and 204 exchange a flag signal FLAG through a separate transmission line TL4. As will be described below, the flag signal FLAG may indicate whether each of a plurality of unit data in the data block DTA is inverted or not.

Further, other pin/transmission line arrangements may be utilized. For example, pins/transmission lines that each transmit and/or receive two or more of address, data and command information (e.g., command/address pins (CA) for the communication of command and address information over shared transmission lines) may be provided. Further, word pins may be used in the generic sense. The word pins should not be considered to be limited to prong type connectors, but may include any communication terminals of a semiconductor device, for example, solder bumps or solder balls in a ball grid array package for electrical communication of signals, and optical terminals for transmitting and receiving optical signals.

Referring to FIGS. 1 and 2, the memory controller 100 may input data to the semiconductor memory device 200a or may output data from the semiconductor memory device 200a through the data pins 103 and 203 based on the request from the host 20. Further, the semiconductor memory device 200a may receive address from the memory controller 100 through the address pins 102 and 202. Further, the semiconductor memory device 200a may receive/input the flag signal FLAG from/to the memory controller 100 through the separate pins 104 and 204.

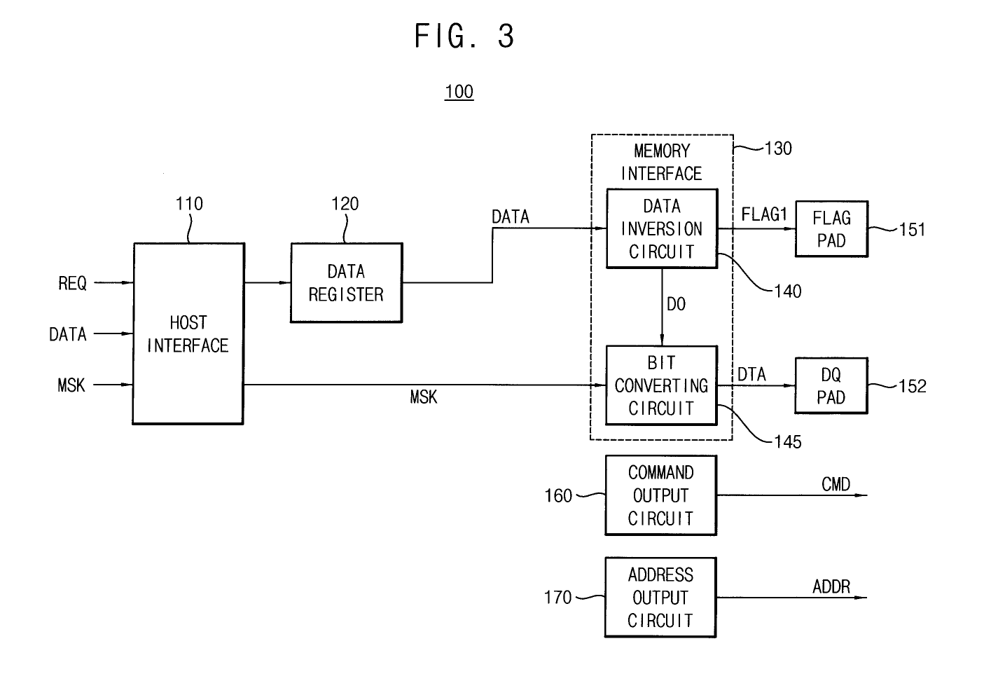

FIG. 3 is block diagram illustrating a memory controller in FIG. 2 according to an example embodiment.

Referring to FIG. 3, the memory controller 100 includes a host interface 110, a data register 120, a memory interface 130, a command output circuit 160 and an address output circuit 170. The memory interface 130 may include a data inversion circuit 140 and a bit converting circuit 145.

The host interface 110 receives a request REQ, data block DATA and a mask information signal MSK from the host 20. The host interface 110 provides the data block DATA to the data register 120 and provides the mask information signal MSK to the memory interface 130.

The data register 120 stores the data block DATA from the host interface 110. The data block DATA stored in the data register 120 may be continuously (or sequentially) output to the data inversion circuit 140. The data block DATA may include a plurality of unit data (e.g., a plurality of byte-unit data).

The data inversion circuit 140 continuously receives the data block DATA, counts a number of data bits having a first logic level in each unit data of the data block DATA, and selectively inverts the unit data based on the number of the data bits having the first logic level in each data unit and provides output data DO to the bit converting circuit 145. For example, when the number of data bits having the first logic level in the data unit is smaller than a desired (or alternatively, predetermined) reference value, the data inversion circuit 140 maintains the unit data and provides the unit data to the bit converting circuit 145 as the output data DO. The desired (or alternatively, predetermined) reference value may have a value that is greater than half of a size of the unit data and is smaller than the size of the unit data. For example, the desired (or alternatively, predetermined) reference value may be five. The first logic level may be data ‘1’. The first logic level may be data ‘0’. Although example embodiments are described assuming that the logic level is data ‘1’, the same description may be applied to a case when the first logic level is data ‘0’.

For example, when the number of data bits having the first logic level in the data unit is equal to or greater than the desired (or alternatively, predetermined) reference value, the data inversion circuit 140 inverts the unit data and provides the inverted unit data to the bit converting circuit 145 as the output data DO. Further, the data inversion circuit 140 may provide a flag pad 151 with a first flag signal FLAG1 indicating whether corresponding unit data is inverted or not. The first flag signal FLAG1 may be provided to the semiconductor memory device 200a through the flag pad 151 and the pin 104.

The data inversion circuit 140 counts the number of data bits having the first logic level in the unit data of current data block DATA and selectively inverts the unit data based on the number of data bits having the first logic level in the data unit. For example, the data inversion circuit 140 may employ direct current (DC) inversion scheme. For example, the data inversion circuit 140 may employ an alternating current (AC) inversion scheme, in which the data inversion circuit 140 counts a number of bit changes between a unit data of a current data block and a unit data of a previous data block immediately preceding the current data block, and selectively inverts data bits of the unit data of the current data block based on the number of bit changes.

The bit converting circuit 145 receives the mask information signal MSK from the host interface 110 and receives the output data DO from the data inversion circuit 140. The number of data bits having the first logic level in the output data DO is smaller than the desired (or alternatively, predetermined) reference value. When the unit data includes one byte, the number of data bits having the first logic level in the output data DO is smaller than the desired (or alternatively, predetermined) reference value, for example, five. That is, the number of data bits having the first logic level in the output data DO may be one of one through four. The bit converting circuit 145 selectively converts, for example, some data bits having the second logic level to data bits having the first logic level such that the number of data bits having the first logic level in corresponding unit data becomes equal to or greater than the desired (or alternatively, predetermined) reference value. The first logic level may be data ‘1’ or data ‘0’.

For example, when the data mask information signal MSK directs data masking operation to the corresponding unit data, the bit converting circuit 145 convert some data bits such that the number of data bits having the first logic level in the corresponding unit data becomes equal to or greater than five and provides unit data of write data block DTA. The corresponding unit data is provided to the semiconductor memory device 200a through the data pad 152 and the data pin 103, and the semiconductor memory device 200a receives the write data block DTA that includes the unit data having a number of data bits having the first logic level equal to or greater than the desired (or alternatively, predetermined) reference value through the data pin 203. Because the number of data bits having the first logic level in the unit data of the write data block DTA is equal to or greater than the desired (or alternatively, predetermined) reference value, the semiconductor memory device 200a performs the data masking operation. Accordingly, the unit data is not written to the memory cell array.

For example, when the data mask information signal MSK directs data write operation to the corresponding unit data, the bit converting unit 145 provides the unit data of the write data block DTA, without converting some data bits having the first logic level to data bits having the second logic level, to the output data DO. The corresponding unit data is provided to the semiconductor memory device 200a through the data pad 152 and the data pin 103, and the semiconductor memory device 200a receives the write data block DTA that includes the unit data having a number of data bits having a first logic level smaller than the desired (or alternatively, predetermined) reference value. Because the number of data bits having the first logic level in the unit data of the write data block DTA is smaller than the desired (or alternatively, predetermined) reference value, the semiconductor memory device 200a performs the data write operation. Accordingly, the unit data is written to the memory cell array.

As described above, the memory interface 130 in the memory controller 100 according to some example embodiments may represent the mask information signal MSK, which indicates whether the data masking operation on the unit data is performed or not, as the number of data bits having the first logic level in the unit data. Accordingly, the semiconductor memory device 200a may perform the masked write operation without transmitting the data mask signal to the semiconductor memory device 200a through separate pins. Thus, the number of the pins required between the semiconductor memory device and the memory controller may be reduced.

The command output unit 160 provides command signal CMD to the semiconductor memory device 200a in response to a signal input from, for example, a central processing unit in the host 20.

The address output unit 170 provides address signal ADDR to the semiconductor memory device 200a in response to a signal input from, for example, the central processing unit in the host 20.

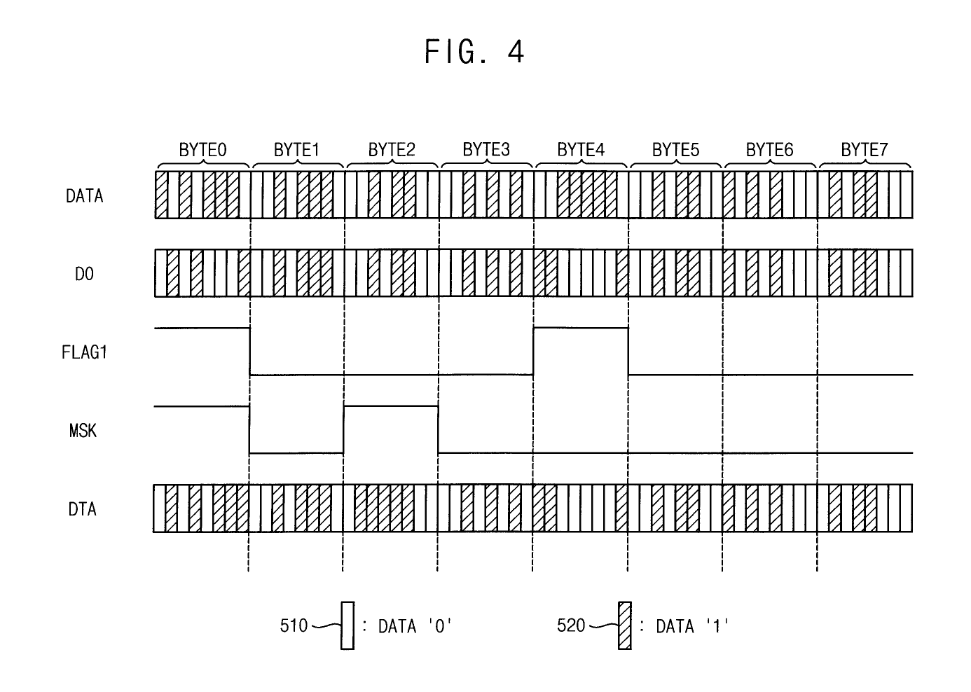

FIG. 4 illustrates data and signals in the memory controller of FIG. 3.

Referring to FIGS. 3 and 4, the data block DATA provided from the data register 120 to the data inversion circuit 140 includes a plurality of unit data BYTE0˜BYTE7, and each of the plurality of unit data BYTE0˜BYTE7 includes one byte. A reference numeral 520 denotes a first logic level, e.g., data ‘1’ and a reference numeral 510 denotes a second logic level, e.g., data ‘0’. Because the number of data bits having the first logic level in a first unit data BYTE0 is five, the data inversion circuit 140 inverts each bit of the first unit data BYTE0 to provide corresponding unit data of the output data DO, and the first flag signal FLAG1 associated with the first unit data BYTE0 is a high logic level. Because the number of data bits having the first logic level in a second unit data BYTE1 is four, the data inversion circuit 140 maintains each bit of the second unit data BYTE1 to provide corresponding unit data of the output data DO, and the first flag signal FLAG1 associated with the second unit data BYTE1 is a low logic level. Because the number of data bits having the first logic level in a third unit data BYTE2 is three, the data inversion circuit 140 maintains each bit of the third unit data BYTE2 to provide corresponding unit data of the output data DO, and the first flag signal FLAG1 associated with the third unit data BYTE2 is a low logic level. Because the number of data bits having the first logic level in a fifth unit data BYTE4 is five, the data inversion circuit 140 inverts each bit of the fifth unit data BYTE4 to provide corresponding unit data of the output data DO, and the first flag signal FLAG1 associated with the fifth unit data BYTE4 is a high logic level.

Referring to FIG. 4, the host interface 10 provides the bit converting circuit 145 with the mask information signal MSK associated with the unit data BYTE0˜BYTE7 as ‘10100000.’ For example, the bit converting circuit 145 converts, for example, two data bits having the second logic level to data bits having the first logic level in the first unit data BYTE0 of the output data DO such that the first unit data BYTE0 of the write data block DTA to be provided to the semiconductor memory device 200a includes five data bits having the first logic level, and thus the data masking operation is performed with respect to the first unit data BYTE0 of the output data DO. Accordingly, the semiconductor memory device 200a performs the data masking operation on the first unit data BYTE0 of the write data block DTA without receiving the data mask signal MSK through separate pins.

Further, the bit converting circuit 145 maintains the number of data bits having the first logic level of the second unit data BYTE1 of the output data DO such that the second unit data BYTE1 of the write data block DTA to be provided to the semiconductor memory device 200a includes the same number of data bits having the first logic level as the output data DO, and thus the data write operation is performed with respect to the second unit data BYTE1 of the output data DO. Accordingly, the semiconductor memory device 200a writes the second unit data BYTE1 of the write data block DTA to the memory cell array.

Further, the bit converting circuit 145 converts, for example, two first data bits having the second logic level to data bits having the first logic level in the third unit data BYTE2 of the output data DO such that the third unit data BYTE2 of the write data block DTA to be provided to the semiconductor memory device 200a includes five data bits having the first logic level, and thus the data masking operation is performed with respect to the third unit data BYTE2 of the output data DO. Accordingly, the semiconductor memory device 200a performs the data masking operation on the third unit data BYTE2 of the write data block DTA without receiving the data mask signal through separate pins.

When the bit converting circuit 145 converts some data bits having the second logic level to data bits having the first logic level in each data unit of the output data DO in response to the mask information signal MSK, the bit converting circuit 145 may randomly convert some data bits having the second logic level to data bits having the first logic level without specifying bit positions of the converted data bits. In some example embodiments, when the bit converting circuit 145 converts some data bits having the second logic level to data bits having the first logic level in each data unit of the output data DO in response to the mask information signal MSK, the bit converting circuit 145 may convert a data bit adjacent to a least significant bit. In this case, the semiconductor memory device 200a may selectively perform the data masking operation on the corresponding unit data by counting the number of data bits having the first logic level in a portion of each unit data of the write data block DTA, instead of counting the number of data bits having the first logic level in each unit data of the write data block DTA. For example, when the mask information signal MSK directs the data masking operation, the bit converting circuit 145 may convert data bits having the first logic level at the bit positions, for example, from the least significant bit to a sixth bit.

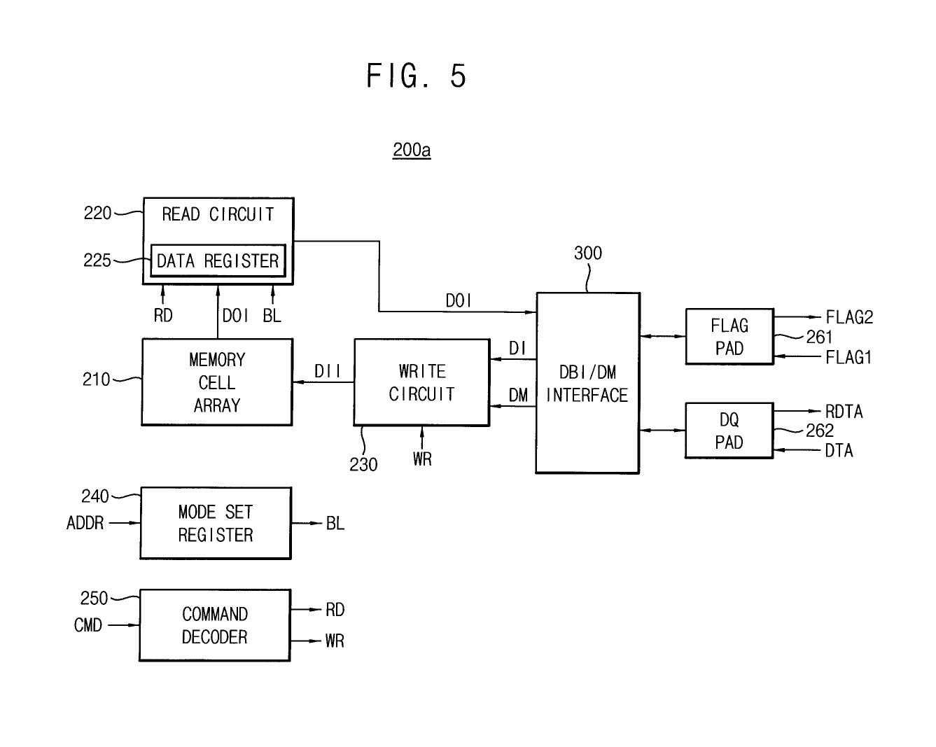

FIG. 5 is a block diagram illustrating a semiconductor memory device in FIG. 2 according to an example embodiment.

Referring to FIG. 5, the semiconductor memory device 200a includes a memory cell array 210, a read circuit 220, a write circuit 230, a mode set register 240, a command decoder 250 and a data inversion/mask interface 300.

The memory cell array 210 includes a plurality of memory cells for storing data. The read circuit 220 includes a data register 225 and performs a data read operation circuit of the semiconductor memory device 200a (e.g., a sense amplifier).

The read circuit 220 may perform a burst read operation that reads a desired (or alternatively, predetermined) number of internal output data DOI stored in the memory cell array 210 in parallel (or simultaneously) in response to a read signal RD and a burst length signal BL and may store the internal output data DOI read in parallel in the data register 225. For example, the data width of the internal output data DOI may be ×8 and the number of internal output data DOI read in parallel may be 4 when the burst length signal BL signal indicates 4. The internal output data DOI stored in the data register 225 may be continuously (or sequentially) output to the data inversion/mask interface 300.

The write circuit 230 may include a circuit related to a data write operation of the semiconductor memory device 200a (e.g., an input driver). The write circuit 230 may perform a burst write operation that writes unit data of input data DI output from the data inversion/mask interface 300 in parallel to the memory cell array 210 in response to a write signal WR. Further, the write circuit 230 may perform data masking operation that masks writing of the corresponding unit data of the input data DI in response to the data mask signal DM from the data inversion/mask interface 300.

The mode set register 240 may generate the burst length signal BL in response to an address signal ADDR provided by the memory controller 100. The command decoder 250 may generate the read signal RD and the write signal WR, which may be synchronized with the clock signal, in response to a command signal CMD provided by the memory controller 100.

The data inversion/mask interface 300 counts a number of data bits having the first logic level in each unit data of the internal output data DOI and selectively inverts each unit data according to the number of data bits having the first logic level in each unit data and provides read data block RDTA including unit data via a data pad 262 to the memory controller 100 and provides a second flag signal FLAG2 via a flag pad 261 to the memory controller 100. The second flag signal FLAG2 indicates whether each unit data is inverted or not.

The data inversion/mask interface 300 receives the first flag signal FLAG1 via the flag pad 261 from the memory controller 100 and receives the write data block DTA from the memory controller 100. The data inversion/mask interface 300 may generate a data mask signal DM associated with each unit data based on the number of data bits having the first logic level in each of the plurality of unit data in the write data block DTA. The data mask signal DM may indicate whether the data masking operation is performed or not on each unit data. When the number of the first data bit in each unit data is equal to or greater than the desired (or alternatively, predetermined) reference value, the data inversion/mask interface 300 may provide the write circuit 230 with the data mask signal DM with a high logic level such that the write circuit 230 does not write the corresponding unit data to the memory cell array 210. When the number of the first data bit in each unit data is smaller than the desired (or alternatively, predetermined) reference value, the data inversion/mask interface 300 may provide the write circuit 230 with the data mask signal DM with a low logic level such that the write circuit 230 writes the corresponding unit data to the memory cell array 210.

In some example embodiments, the unit data may have a first data size. When the number of the first data bit in a second data size smaller than the first data size of each unit data is equal to or greater than a desired (or alternatively, predetermined) reference value, the data inversion/mask interface 300 may provide the write circuit 230 with the data mask signal DM with a high logic level such that the write circuit 230 does not write the corresponding unit data to the memory cell array 210. When the number of data bits having the first logic level in the second data size of each unit data is smaller than the desired (or alternatively, predetermined) reference value, the data inversion/mask interface 300 may provide the write circuit 230 with the data mask signal DM with a low logic level such that the write circuit 230 writes the corresponding unit data to the memory cell array 210. The second data size may be smaller than the first data size and may be greater than half of the first data size. For example, the second data size may be greater than the half of the first data size by two.

In addition, the data inversion/mask interface 300 may selectively invert each unit data of the write data block DTA to provide an input data DI to the write circuit 230, in response to the first flag signal FLAG1. For example, when the first flag signal FLAG1 is a high logic level, the data inversion/mask interface 300 may invert corresponding unit data of the write data block DTA to be provided to the write circuit 230. The write circuit 230 writes the received unit data to the memory cell array 210 when the data mask signal DM is a low logic level and the write circuit 240 does not write the received unit data to the memory cell array 210 when the data mask signal DM is a high logic level.

The semiconductor memory device 200a may selectively perform one of the write operation and the data masking operation on the corresponding unit data based on the number of data bits having the first logic level in the corresponding unit data without receiving the data mask signal through separate pins.

In some example embodiments, the data inversion/mask interface 300 may count the number of data bits having the first logic level in the unit data and determines whether the data masking operation is performed based on the counted number of data bits having the first logic level in the unit data. In some example embodiments, the data inversion/mask interface 300 may count the number of data bits having the first logic level in a portion of the unit data and determines whether the data masking operation is performed based on the counted number of data bits having the first logic level in the portion of the unit data.

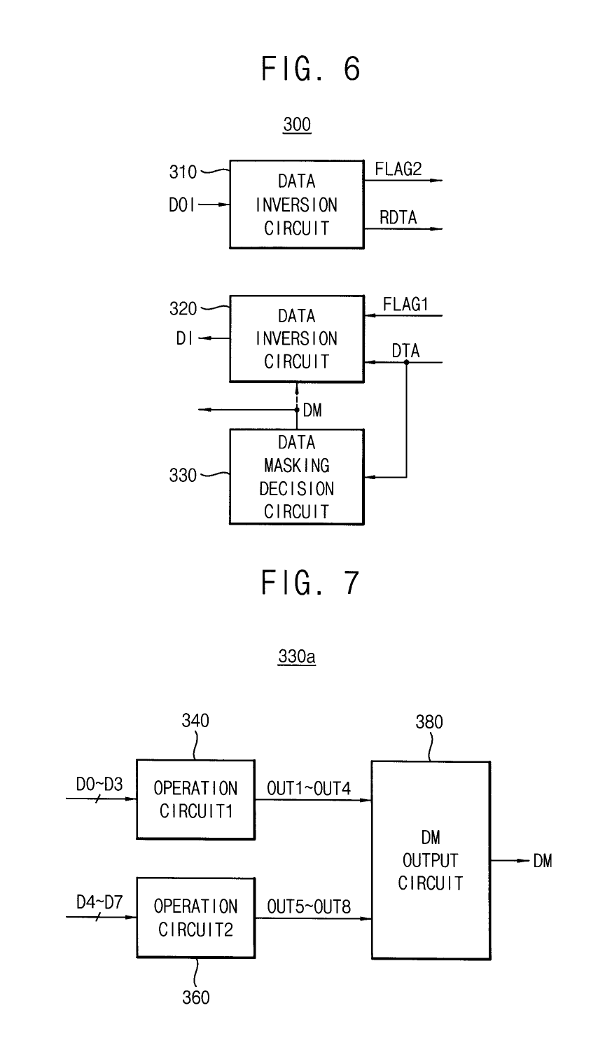

FIG. 6 is a block diagram illustrating the data inversion/mask interface in FIG. 5 according to an example embodiment.

Referring to FIG. 6, the data inversion/mask inversion interface 300 may include first and second data inversion circuits 310 and 320 and a data masking decision circuit 330.

The first data inversion circuit 310 may selectively invert each unit data of the internal output data DOI from the data register 225 based on the number of data bits having the first logic level in each unit data to provide internal output data DOI to the memory controller 100 as read data block RDTA and simultaneously provide the second flag signal FLAG2 to the memory controller 100 via the flag pad 261. The second flag signal FLAG2 indicates whether each unit data of the read data block RDTA is inverted or not.

The second inversion circuit 320 may receive the first flag signal FLAG1 and the write data block DTA from the memory controller 100. The second inversion circuit 320 may selectively invert each unit data of the write data block DTA in response to the first flag signal FLAG1 and provide the input data DI to the write circuit 320.

The data masking decision circuit 330 receives the write data block DTA from the memory controller 100 and provides the write circuit 230 with the data mask signal DM. The data mask signal may be enabled when the number of data bits having the first logic level in each unit data is equal to or greater than the desired (or alternatively, predetermined) reference value. The write circuit 230 may selectively perform one of the write operation and the data masking operation (or masked write operation) on the corresponding unit data, in response to the data mask signal DM. Further, the data masking decision unit 330 may provide the data mask signal DM to the second data inversion circuit 320. The second data inversion circuit 320 may selectively invert the corresponding unit data in response to the data mask signal DM even when the first flag signal FLAG1 is a high logic level. For example, when the first flag signal FLAG1 is a high logic level and the data mask signal DM is a high logic level, the second data inversion circuit 320 does not invert the corresponding unit data because the corresponding unit data will not be written in the memory cell array 210.

FIG. 7 is a block diagram illustrating an example of the data masking decision circuit in FIG. 6 according to an example embodiment.

Referring to FIG. 7, a data masking decision unit 330a includes first and second operation circuits 340 and 360 and a data mask signal output circuit 380. The first operation circuit 340 operates on less significant half data bits D0˜D3 of the unit data to generate first output signals OUT1˜OUT4 having a desired (or alternatively, predetermined) pattern according to a number of data bits having the first logic level in the less significant half data bits D0˜D3. The second operation circuit 360 operates more significant half data bits D4˜D7 of the unit data to generate second output signals OUT5˜OUT8 having a desired (or alternatively, predetermined) pattern according to a number of data bits having the first logic level in the more significant half data bits D4˜D7. The data mask signal output circuit 380 operates on the first output signals OUT1˜OUT4 and the second output signals OUT5˜OUT8 to provide the data mask signal DM. For example, the data mask signal output circuit 380 may output the data mask signal DM having a high logic level, when the number of data bits having the first logic level in the unit data is equal to or greater than the desired (or alternatively, predetermined) reference value.

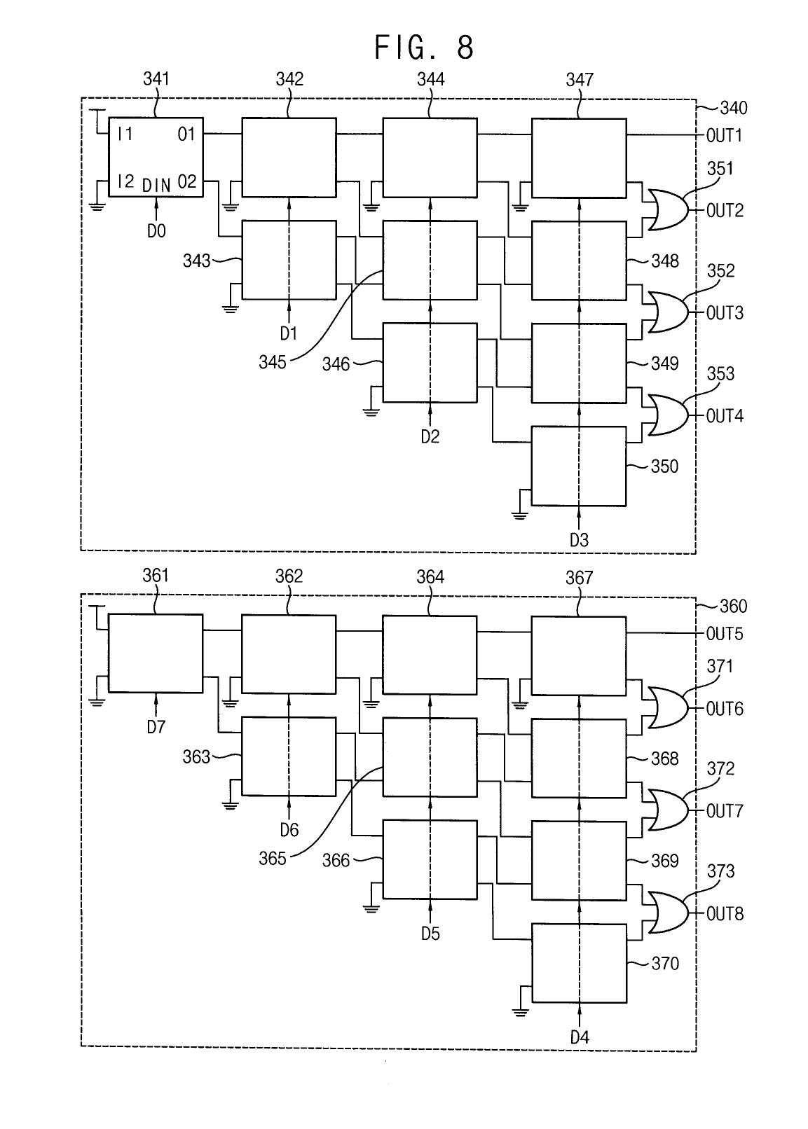

FIG. 8 illustrates the first and second operation circuits in FIG. 7 according to an example embodiment.

Referring to FIG. 8, the first operation circuit 340 includes a plurality of unit logics 341˜350 and OR gates 351˜353 and the second operation circuit 360 includes a plurality of unit logics 361˜370 and OR gates 371˜373.

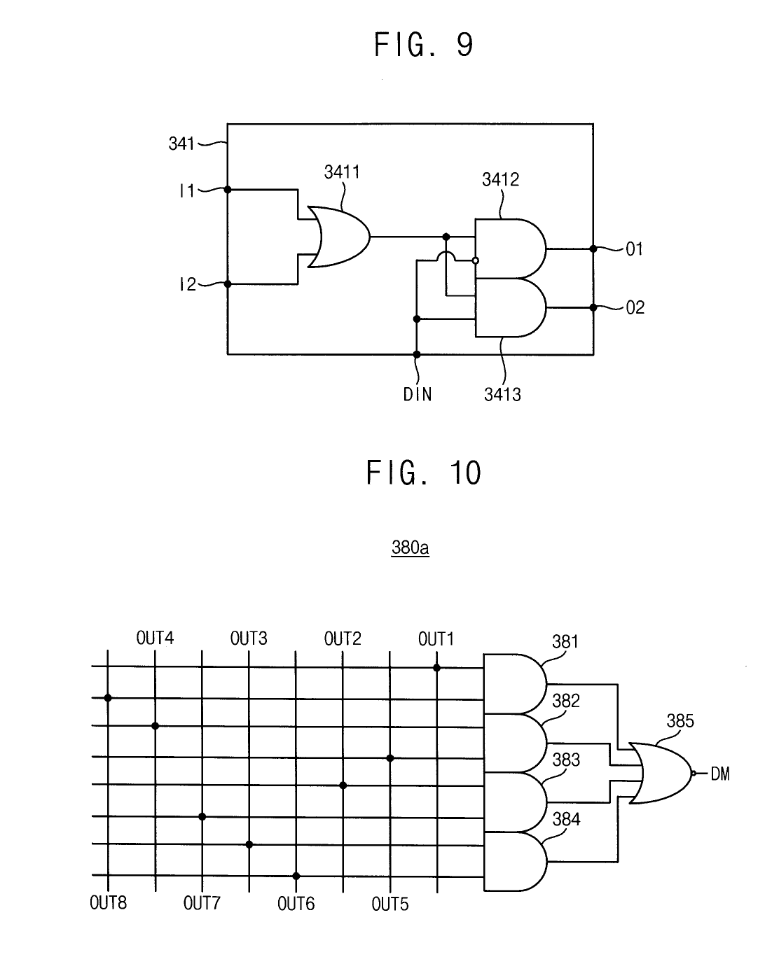

FIG. 9 is a circuit diagram illustrating one of the unit logics in FIG. 8 according to an example embodiment.

Referring to FIG. 9, the unit logic 341 includes first and second input terminals 11 and 12, an OR gate 3411, AND gates 3412 and 3413, a data input terminal DIN, and first and second output terminals O1 and O2. When both of two input signals input to the first and second input terminals 11 and 12 are low logic levels, the first and second output terminals O1 and O2 provide two output signals having a low logic level without regard to a logic level of data bit input to the data input terminal DIN. Except the case in which both of two input signals have a low logic level, the second output terminal O2 provides an output signal having the same logic level as the data bit input to the data input terminal DIN and the first output terminal O1 provides an output signal having different (e.g., complementary) logic level from the data bit input to the data input terminal DIN.

Referring again to FIG. 8, a data bit D0 is input to the unit logic 341, a data bit D1 is input to the unit logics 342 and 343, a data bit D2 is input to the unit logics 344, 345 and 346, and a data bit D3 is input to the unit logics 347, 348, 349 and 350. Further, a data bit D7 is input to the unit logic 361, a data bit D6 is input to the unit logics 362 and 363, a data bit D5 is input to the unit logics 364, 365 and 366, and a data bit D4 is input to the unit logics 367, 368, 369 and 370. The first output terminal of the unit logic 347 provides the output signal OUT1, the OR gate 351 performs OR operation on a second output of the unit logic 347 and a first output of the unit logic 348 to provide the output signal OUT2, the OR gate 352 performs OR operation on a second output of the unit logic 348 and a first output of the unit logic 349 to provide the output signal OUT3, and the OR gate 353 performs OR operation on a second output of the unit logic 349 and a first output of the unit logic 350 to provide the output signal OUT4. The unit logics 361˜370 and the OR gates 371˜373 are similarly connected as illustrated in FIG. 8.

When the number of data bits having the first logic level in less significant half data bits D0˜D3 is 0, the first output signals OUT1˜OUT4 corresponds to ‘1000’. When the number of data bits having the first logic level in the less significant half data bits D0˜D3 is 1, the first output signals OUT1˜OUT4 corresponds to ‘0100’. When the number of data bits having the first logic level in the less significant half data bits D0˜D3 is 2, the first output signals OUT1˜OUT4 corresponds to ‘0010’. When the number of data bits having the first logic level in the less significant half data bits D0˜D3 is 3, the first output signals OUT1˜OUT4 corresponds to ‘0001’. When the number of data bits having the first logic level in the less significant half data bits D0˜D3 is 4, the first output signals OUT1˜OUT4 corresponds to ‘0000’.

When the number of data bits having the first logic level in more significant half data bits D4˜D7 is 0, the second output signals OUT5˜OUT8 corresponds to ‘1000’. When the number of data bits having the first logic level in the more significant half data bits D4˜D7 is 1, the second output signals OUT5˜OUT8 corresponds to ‘0100’. When the number of data bits having the first logic level in the more significant half data bits D4˜D7 is 2, the second output signals OUT5˜OUT8 corresponds to ‘0010’. When the number of data bits having the first logic level in the more significant half data bits D4˜D7 is 3, the second output signals OUT5˜OUT8 corresponds to ‘0001’. When the number of data bits having the first logic level in the more significant half data bits D4˜D7 is 4, the second output signals OUT5˜OUT8 corresponds to ‘0000’. Therefore, the first output signals OUT1˜OUT4 has a desired (or alternatively, predetermined) pattern according to the number of data bits having the first logic level in the less significant half data bits D0˜D3, and the second output signals OUT5˜OUT8 has a desired (or alternatively, predetermined) pattern according to the number of data bits having the first logic level in the more significant half data bits D4˜D7.

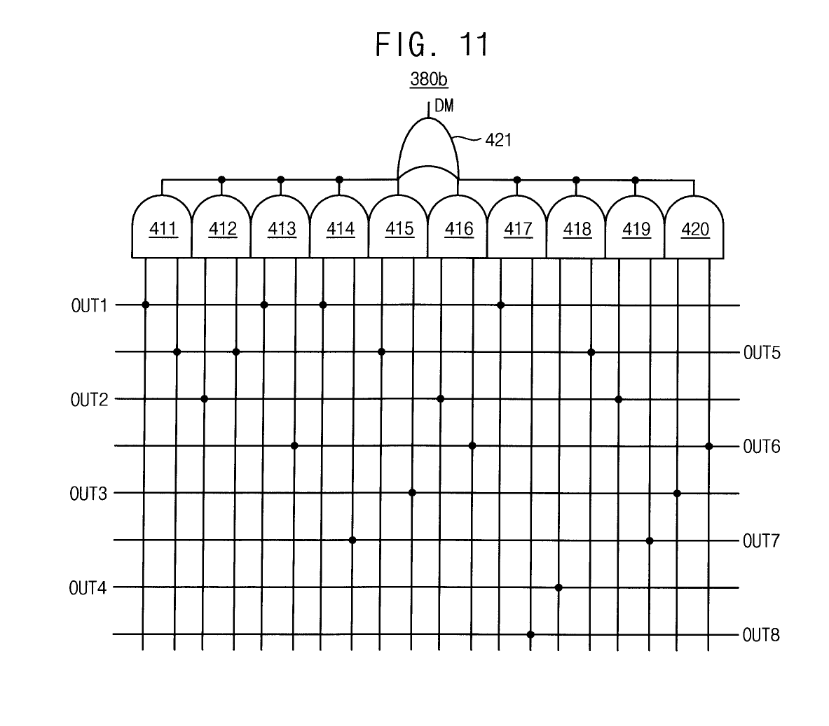

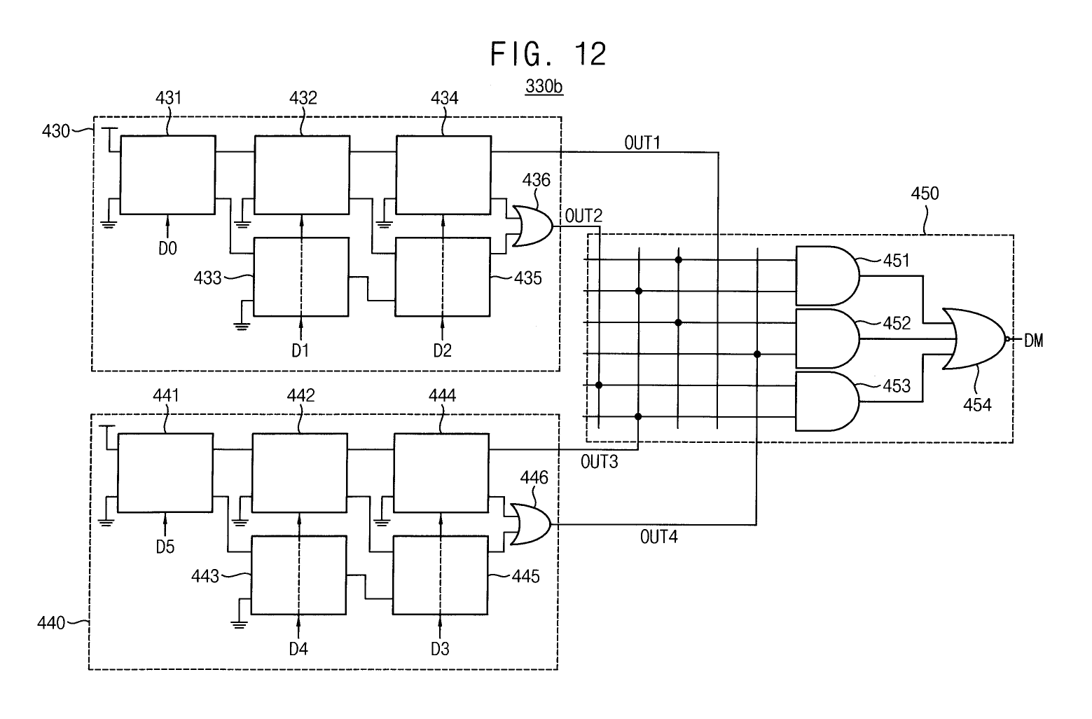

FIG. 10 is circuit diagram illustrating an example of the data mask signal output circuit in FIG. 7 according to an example embodiment.

Referring to FIG. 10, a data mask signal output circuit 380a includes AND gates 381˜384 and a NOR gate 385.

The AND gate 381 performs AND operation on the output signals OUT1 and OUT8 to provide an output to the NOR gate 385. Therefore, the output of the AND gate 381 becomes a high logic level when the number of data bits having the first logic level in the less significant half data bits D0˜D3 is 0 and the number of data bits having the first logic level in the more significant half data bits D4˜D7 is 3. The AND gate 382 performs AND operation on the output signals OUT4 and OUT5 to provide an output to the NOR gate 385. The AND gate 383 performs AND operation on the output signals OUT2 and OUT7 to provide an output to the NOR gate 385. The AND gate 384 performs AND operation on the output signals OUT3 and OUT6 to provide an output to the NOR gate 385. Therefore, the NOR gate 385 provides the data mask signal DM having a high logic level when the number of data bits having the first logic level in the unit data is equal to or greater than 5.

FIG. 11 is circuit diagram illustrating an example of the data mask signal output circuit in FIG. 7 according to an example embodiment.

Referring to FIG. 11, a data mask signal output circuit 380b includes AND gates 411˜420 and an OR gate 421.

The first and second output signals OUT1˜OUT4 and OUT5˜OUT8 are input to the AND gates 411˜420 as illustrated in FIG. 11 and outputs of the AND gates 411˜420 are provided to the OR gate 421. The OR gate 421 provides the data mask signal DM having a high logic level when the number of data bits having the first logic level in the unit data is equal to or greater than 5.

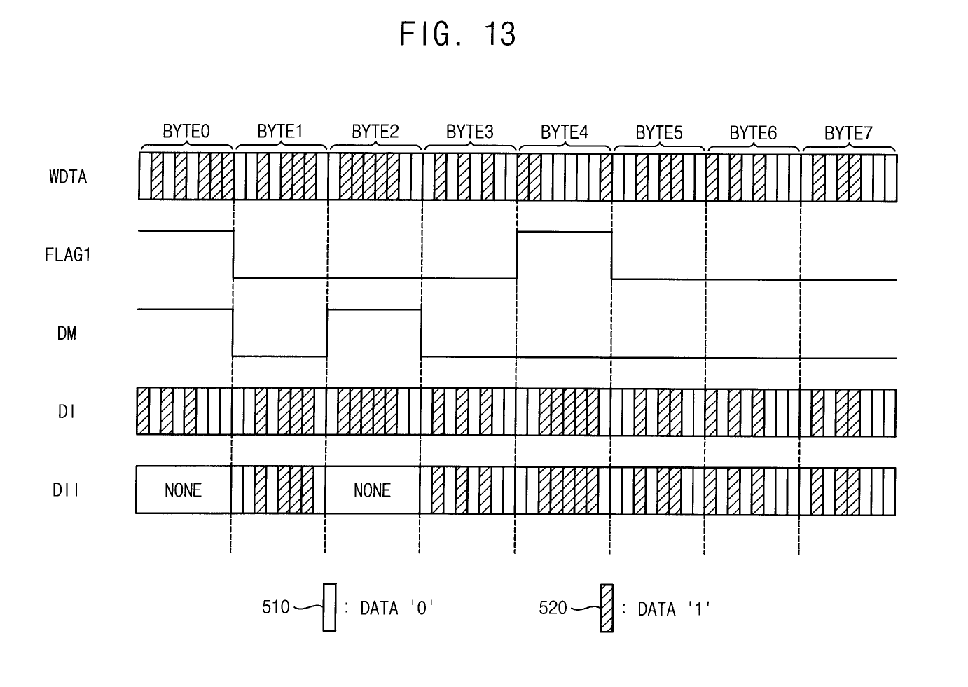

FIG. 12 is a block diagram illustrating an example of the data masking decision circuit in FIG. 6 according to an example embodiment.

Referring to FIG. 12, a data masking decision circuit 330b includes first and second operation circuits 430 and 440 and a data mask signal output circuit 450.

The first operation circuit 430 includes a plurality of unit logics 431˜435 and an OR gate 436 and the second operation circuit 440 includes a plurality of unit logics 441˜445 and an OR gate 446. The data mask signal output circuit 450 includes a plurality of AND gates 451˜453 and a NOR gate 454. Each of the unit logics 431˜435 and the unit logics 441˜445 may employ the unit logic 341 of FIG. 9. The unit logics 431˜435 of the first operation circuit 430 receives less significant half bits D0˜D2 of rest data bits D0˜D5. The rest data bits D0˜D5 may be obtaining by omitting at least two more significant bits D6 and D7 from the unit data. The unit logics 441˜445 of the first operation circuit 440 receives more significant half bits D3˜D5 of the rest data bits D0˜D5. The first output terminal of the unit logic 434 provides the output signal OUT1 and the OR gate 436 performs an OR operation on a second output of the unit logic 434 and a first output of the unit logic 435 to provide the output signal OUT2. The first output terminal of the unit logic 444 provides the output signal OUT3 and the OR gate 446 performs an OR operation on a second output of the unit logic 444 and a first output of the unit logic 445 to provide the output signal OUT4.

When the number of data bits having the first logic level in the less significant half data bits D0˜D2 is 0, the first output signals OUT1 and OUT2 corresponds to ‘10’. When the number of data bits having the first logic level in the less significant half data bits D0˜D2 is 1, the first output signals OUT1 and OUT2 corresponds to ‘01’. When the number of data bits having the first logic level in the more significant half data bits D3˜D5 is 0, the first output signals OUT3 and OUT4 corresponds to ‘10’. When the number of data bits having the first logic level in the more significant half data bits D3˜D5 is 1, the first output signals OUT3 and OUT4 corresponds to ‘01’. When the AND gates 451˜453 receives the output signals OUT1˜OUT4 as illustrated in FIG. 12, the NOR gate 454 provides the data mask signal DM having a high logic level when the number of data bits having the first logic level in the rest data bits D0˜D5 is equal to or greater than 5.

FIG. 13 illustrates data and signals in the semiconductor memory device of FIG. 5.

Referring to FIGS. 5, 6 and 13, when write data block WDTA from the memory controller 100 corresponds to the write data block DTA in FIG. 4, the write data block WDTA includes a plurality of unit data BYTE0˜BYTE7, and each of the plurality of unit data BYTE0˜BYTE7 includes one byte. A reference numeral 520 denotes a high logic level data, e.g., data ‘1’ and a reference numeral 510 denotes a low logic level data, e.g., data ‘0’.

Because the number of data bits having the first logic level in a first unit data BYTE0 is five and the first flag signal FLAG1 associated with the first unit data BYTE0 is high logic level, the first data inversion circuit 310 inverts the first unit data BYTE0 to be provided to the write circuit 230. Because the number of data bits having the first logic level in the first unit data BYTE0 is five, which is equal to the desired (or alternatively, predetermined) reference value, the data masking decision circuit 330 provides an enabled data mask signal DM to the write circuit 230. The write circuit 230 performs a data masking operation that does not write the first unit data BYTE0 to the memory cell array 210 in response to the data mask signal DM.

Because the number of data bits having the first logic level in a second unit data BYTE1 is 4 and the first flag signal FLAG1 associated with the second unit data BYTE1 is a low logic level, the first data inversion circuit 310 maintains the second unit data BYTE1 to be provided to the write circuit 230. Because the number of data bits having the first logic level in the second unit data BYTE1 is four, which is smaller than the desired (or alternatively, predetermined) reference value, the data masking decision circuit 330 provides a disabled data mask signal DM to the write circuit 230. The write circuit 230 performs a data write operation that writes the second unit data BYTE1 to the memory cell array 210 in response to the data mask signal DM.

Because the number of data bits having the first logic level in a third unit data BYTE2 is five and the first flag signal FLAG1 associated with the third unit data BYTE2 is a low logic level, the first data inversion circuit 310 maintains the third unit data BYTE2 to be provided to the write circuit 230. Because the number of data bits having the first logic level in the third unit data BYTE2 is five, which is equal to the desired (or alternatively, predetermined) reference value, the data masking decision circuit 330 provides an enabled data mask signal DM to the write circuit 230. The write circuit 230 performs a data masking operation that does not write the third unit data BYTE2 to the memory cell array 210 in response to the data mask signal DM. In FIG. 13, input data block DI is provided to the write circuit 230 from the data inversion/mask interface 300, and the write circuit 230 writes data block DII in the memory cell array 210.

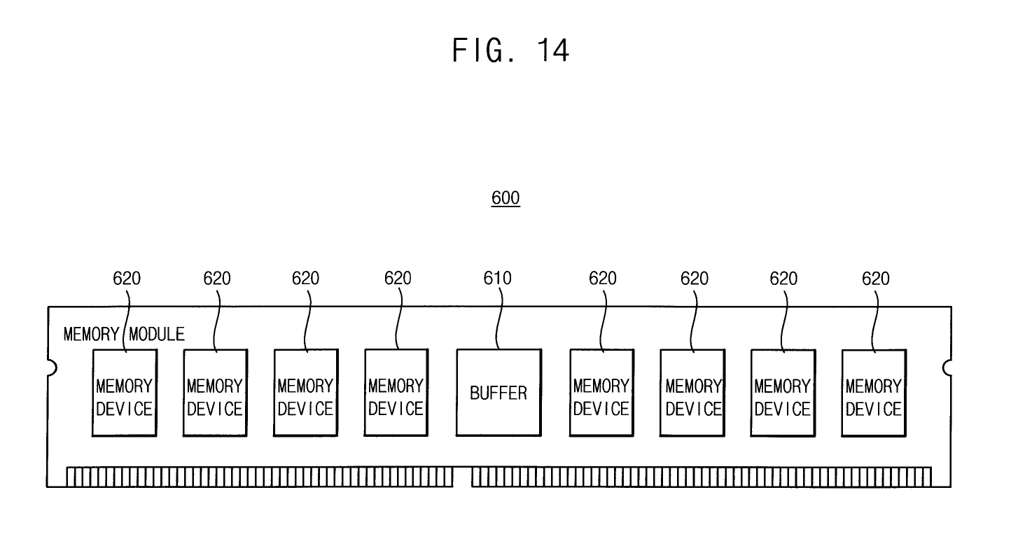

As described above, the semiconductor memory device 200a according to some example embodiments may selectively perform one of the write operation and the masked write operation on the corresponding unit data based on the number of data bits having the first logic level in the corresponding unit data. Therefore, the semiconductor memory device 200a may perform the masked write operation without transmitting the data mask signal to the semiconductor memory device 200a through separate pins. Thus, the number of the pins required for communication between the semiconductor memory device and the memory controller may be reduced. FIG. 14 is a block diagram illustrating a memory module including the semiconductor memory device according to an example embodiment.

Referring to FIG. 14, a memory module 600 may include a plurality of semiconductor memory devices 620. In some embodiments, the memory module 600 may be, for example, an un-buffered dual in-line memory module (UDIMM), a registered dual in-line memory module (RDIMM), a fully buffered dual in-line memory module (FBDIMM), or a load reduced dual in-line memory module LRDIMM.

The memory module 600 may further a buffer 610 that provides, for example, a command/address signal, data and a flag signal by buffering the command/address signal, and the data from a memory controller through a plurality of transmission lines. In some example embodiments, data transmission lines between the buffer 610 and the semiconductor memory devices 620 may be coupled, for example, in a point-to-point topology, and command/address transmission lines between the buffer 610 and the semiconductor memory devices 620 may be coupled, for example, in a multi-drop topology, a daisy-chain topology, or a fly-by daisy-chain topology. Because the buffer 610 buffers both the command/address signal and the data, the memory controller may interface with the memory module 600 by driving only a load of the buffer 610. Accordingly, the memory module 600 may include more semiconductor memory devices and/or more memory ranks, and a memory system may include more memory modules.

Each of the semiconductor memory devices 620 may employ the semiconductor memory device 200a of FIG. 5. Therefore, each of the semiconductor memory devices 620 may selectively perform one of the data masking operation that does not write corresponding unit data to the memory cell array when the number of data bits having a first logic level in unit data of data from the buffer 610 is equal to or greater than the desired (or alternatively, predetermined) reference value and the write operation that writes the corresponding unit data in the memory cell array when the number of data bits having the first logic level in the unit data is smaller than the desired (or alternatively, predetermined) reference value. Therefore, each of the semiconductor memory devices 620 may perform the masked write operation without transmitting to each of the semiconductor memory devices 620 through separate pins. Thus, the number of the pins required for communication between the semiconductor memory devices and the memory controller may be reduced.

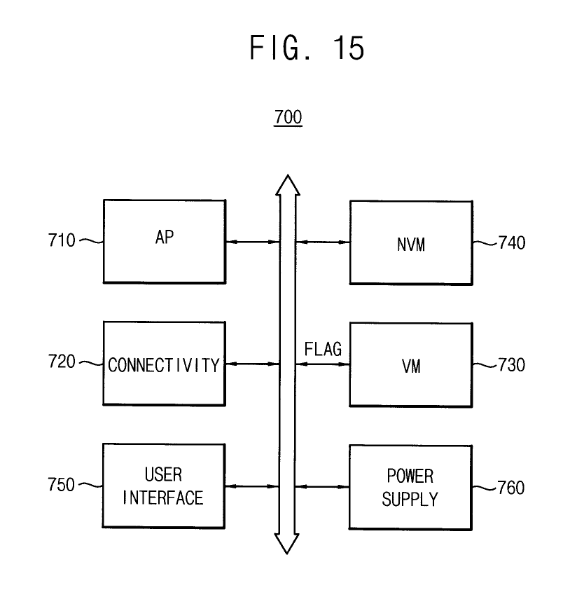

FIG. 15 is a block diagram illustrating a mobile system according to an example embodiment.

Referring to FIG. 15, a mobile system 700 includes an application processor (AP) 710, a connectivity unit 720, a volatile memory device (VM) 730, a nonvolatile memory (NVM) device 740, a user interface 750 and a power supply 760. In some example embodiments, the mobile system 700 may be, for example, a mobile phone, a smart phone, a personal digital assistant (PDA), a portable multimedia player (PMP), a digital camera, a music player, a portable game console, or a navigation system.

The application processor 710 may execute applications, for example, a web browser, a game application, or a video player. In some example embodiment, the application processor 710 may include a single core or multiple cores. For example, the application processor 710 may be a multi-core processor, for example, a dual-core processor, a quad-core processor, or a hexa-core processor. The application processor 710 may include an internal or external cache memory.

The connectivity unit 720 may perform wired or wireless communication with an external device. For example, the connectivity unit 720 may perform, for example, ethernet communication, near field communication (NFC), radio frequency identification (RFID) communication, mobile telecommunication, memory card communication, or universal serial bus (USB) communication. In some example embodiments, the connectivity unit 720 may include a baseband chipset that supports communications, for example, global system for mobile communications (GSM), general packet radio service (GPRS), wideband code division multiple access (WCDMA), or high speed downlink/uplink packet access (HSxPA).

The volatile memory device 730 may store data processed by the application processor 710, or may operate as a working memory. The volatile memory device 730 may be a dynamic random access memory, for example, DDR SDRAM, LPDDR SDRAM, GDDR SDRAM, or RDRAM. The volatile memory device 730 may selectively invert or not invert input data or output data in response to a flag signal from the application processor 710. The volatile memory device 730 may employ the semiconductor memory device 200a of FIG. 5. Accordingly, the volatile memory device 730 may selectively perform one of the data masking operation and the write operation. The data masking operation refers to an operation that does not write corresponding unit data to the memory cell array when the number of data bits having a first logic level in unit data of data from the application processor 710 is equal to or greater than the desired (or alternatively, predetermined) reference value. The write operation refers to an operation that writes the corresponding unit data in the memory cell array when the number of data bits having the first logic level in the unit data is smaller than the desired (or alternatively, predetermined) reference value. Therefore, the volatile memory device 730 may perform the masked write operation without transmitting the data mask signal to volatile memory device 730 through separate pins. Thus, the number of the required pins for the volatile memory device 730 may be reduced.

The nonvolatile memory device 740 may store a boot image for booting the mobile system 700. For example, the nonvolatile memory device 740 may be, for example, an electrically erasable programmable read-only memory (EEPROM), a flash memory, a phase change random access memory (PRAM), a resistance random access memory (RRAM), a nano floating gate memory (NFGM), a polymer random access memory (PoRAM), a magnetic random access memory (MRAM), or a ferroelectric random access memory (FRAM).

The user interface 750 may include at least one input device, for example, a keypad or a touch screen, and at least one output device, for example, a speaker or a display device. The power supply 760 may supply a power supply voltage to the mobile system 700. In some example embodiments, the mobile system 700 may further include a camera image processor (CIS), and/or a storage device (e.g., a memory card, a solid state drive (SSD), a hard disk drive (HDD), or a CD-ROM).

In some example embodiments, the mobile system 700 and/or components of the mobile system 700 may be packaged in various forms, for example, package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi-chip package (MCP), wafer-level fabricated package (WFP), or wafer-level processed stack package (WSP).

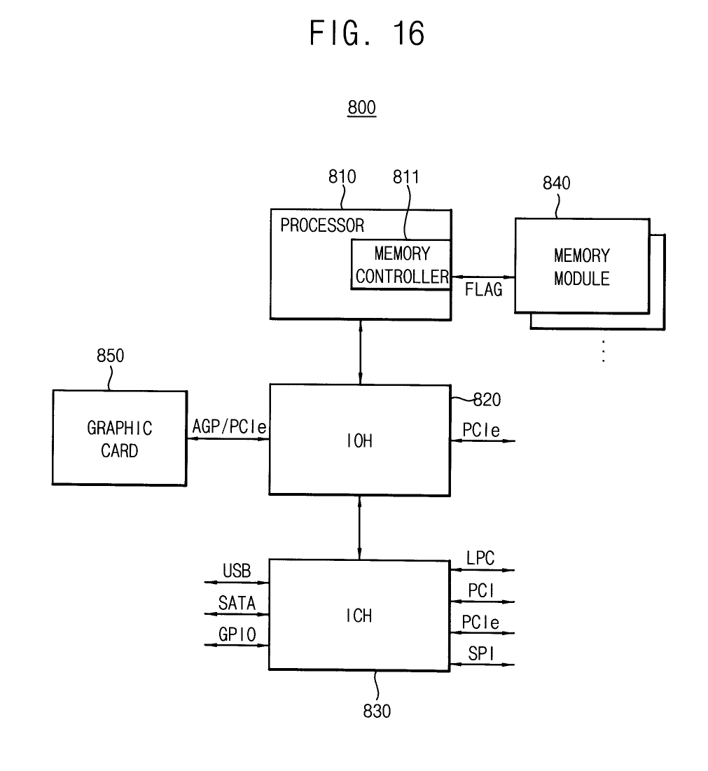

FIG. 16 is a block diagram illustrating a computing system according to an example embodiment.

Referring to FIG. 16, a computing system 800 includes a processor 810, an input/output hub (IOH) 820, an input/output controller hub (ICH) 830, at least one memory module 840 and a graphics card 850. In some example embodiments, the computing system 800 may be, for example, a personal computer (PC), a server computer, a workstation, a laptop computer, a mobile phone, a smart phone, a personal digital assistant (PDA), a portable multimedia player (PMP), a digital camera), a digital television, a set-top box, a music player, a portable game console, or a navigation system.

The processor 810 may perform various computing functions, for example, executing specific software for performing specific calculations or tasks. The processor 810 may be, for example, a microprocessor, a central process unit (CPU), or a digital signal processor. In some example embodiments, the processor 810 may include a single core or multiple cores. For example, the processor 810 may be a multi-core processor, for example, a dual-core processor, a quad-core processor, or a hexa-core processor. Although FIG. 16 illustrates the computing system 800 including a single processor 810, the computing system 800 of example embodiments is not limited thereto and may include a plurality of processors. The processor 810 may include an internal or external cache memory.

The processor 810 may include a memory controller 811 for controlling operations of the memory module 840. The memory controller 811 included in the processor 810 may be referred to as an integrated memory controller (IMC). A memory interface between the memory controller 811 and the memory module 840 may be implemented with a single channel including a plurality of signal lines, or may be implemented with multiple channels, to each of which at least one memory module 840 may be coupled. In some example embodiments, the memory controller 811 may be located inside the input/output hub 820, which in such case, may be referred to as memory controller hub (MCH).

The memory module 840 may include a plurality of semiconductor memory devices that store data provided from the memory controller 811. The semiconductor memory devices may selectively invert or not invert input data or output data in response to a flag signal FLAG to/from the processor 810. Each of the semiconductor memory devices may employ the semiconductor memory device 200a of FIG. 5. Therefore, each of the semiconductor memory devices may selectively perform one of the data masking operation or the write operation. The data masking operation refers to an operation that does not write corresponding unit data to the memory cell array when the number of data bits having the first logic level in unit data of data from the memory controller 811 is equal to or greater than the desired (or alternatively, predetermined) reference value. The write operation refers to an operation that writes the corresponding unit data in the memory cell array when the number of data bits having the first logic level in the unit data is smaller than the desired (or alternatively, predetermined) reference value. Therefore, each of the semiconductor memory devices may perform the masked write operation without transmitting the data mask signal to the semiconductor memory device through separate pins. Thus, the number of the pins required for communication between the semiconductor memory devices and the memory controller may be reduced.

The input/output hub 820 may manage data transfer between processor 810 and devices, such as the graphics card 850. The input/output hub 820 may be coupled to the processor 810 via various interfaces. For example, the interface between the processor 810 and the input/output hub 820 may be, for example, a front side bus (FSB), a system bus, a HyperTransport, a lightning data transport (LDT), a QuickPath interconnect (QPI), or a common system interface (CSI). Although FIG. 16 illustrates the computing system 800 including one input/output hub 820, the computing system 800 according to example embodiments is not limited there to and may include a plurality of input/output hubs. The input/output hub 820 may provide various interfaces with respect to the devices. For example, the input/output hub 820 may provide, for example, an accelerated graphics port (AGP) interface, a peripheral component interface-express (PCIe), or a communications streaming architecture (CSA) interface.

The graphics card 850 may be coupled to the input/output hub 820 via, for example, AGP or PCIe. The graphics card 850 may control a display device (not shown) for displaying an image. The graphics card 850 may include an internal processor for processing image data and an internal memory device. In some example embodiment, the input/output hub 820 may include an internal graphics device instead of (or in addition to) the graphics card 850. The graphics device included in the input/output hub 820 may be referred to as integrated graphics. Further, the input/output hub 820 including the internal memory controller and the internal graphics device may be referred to as a graphics and memory controller hub (GMCH).

The input/output controller hub 830 may perform data buffering and interface arbitration to efficiently operate various system interfaces. The input/output controller hub 830 may be coupled to the input/output hub 820 via an internal bus, for example, a direct media interface (DMI), a hub interface, an enterprise Southbridge interface (ESI), or PCIe. The input/output controller hub 830 may provide various interfaces with peripheral devices. For example, the input/output controller hub 830 may provide a universal serial bus (USB) port, a serial advanced technology attachment (SATA) port, a general purpose input/output (GPIO), a low pin count (LPC) bus, a serial peripheral interface (SPI), PCI, or PCIe.

In some example embodiments, the processor 810, the input/output hub 820 and the input/output controller hub 830 may be implemented as separate chipsets or separate integrated circuits. In other embodiments, at least two of the processor 810, the input/output hub 820, and the input/output controller hub 830 may be implemented as a single chipset.

Therefore, according to various example embodiments, a memory controller converts some data bits having the second logic level to data bits having the first logic level in each of unit data to be provided to a semiconductor memory device when data masking operation is to be performed and the semiconductor memory device may selectively perform one of the data masking operation and the write operation. The data masking operation refers to an operation that does not write corresponding unit data to the memory cell array when the number of data bits having the first logic level in a unit data from the memory controller is equal to or greater than the desired (or alternatively, predetermined) reference value. The write operation refers to an operation that writes the corresponding unit data in the memory cell array when the number of data bits having the first logic level in the unit data is smaller than the desired (or alternatively, predetermined) reference value. Therefore, the semiconductor memory device may perform the masked write operation based on the number of data bits having the first logic level without transmitting to the semiconductor memory device through separate pins. Thus, the number of pins required for communication between the semiconductor memory device and the memory controller may be reduced.

The present inventive concepts may be applied to systems using memory controllers and semiconductor memory devices. The present inventive concepts may be applied to systems, for example, a mobile phone, a smart phone, a personal digital assistant (PDA), a portable multimedia player (PMP), a digital camera, a music player, a portable game console, or a navigation system. The foregoing is illustrative of example embodiments and is not to be construed as limiting thereof.

Although a few example embodiments have been described, those skilled in the art will readily appreciate that many modifications are possible in the example embodiments without materially departing from the novel teachings and advantages of the present inventive concepts. Accordingly, all such modifications are intended to be included within the scope of the present inventive concepts as defined in the claims.

What is claimed is:

1. A semiconductor memory device comprising:
a memory cell array;
a data inversion/mask interface configured to receive a data block including a plurality of unit data, each of the plurality of unit data having a first data size, the data inversion/mask interface configured to selectively enable each data mask signal associated with each of the plurality of unit data based on a number of data bits having a first logic level in a portion of each of the plurality of unit data, the portion having a second data size, and the second data size being smaller than the first data size; and
a write circuit configured to receive the data block and configured to perform a masked write operation that selectively writes each of the plurality of unit data in the memory cell array in response to the data mask signal.

2. The semiconductor memory device of claim 1, wherein the second data size is greater than half of the first data size.

3. The semiconductor memory device of claim 2, wherein the first data size corresponds to a size of one byte, and the second data size corresponds to a value which is greater than half of the first data size by two.

4. The semiconductor memory device of claim 1, wherein the data inversion/mask interface is configured to enable the data mask signal when the number of data bits having the first logic level in the portion of each of the plurality of unit data is equal to or greater than a reference value.

5. The semiconductor memory device of claim 4, wherein when the first data size is eight, the reference value is five.

6. The semiconductor memory device of claim 1, wherein the first logic level is one of data ‘1’ and data ‘0’.

7. The semiconductor memory device of claim 1, wherein the data inversion/mask interface comprises:
a data masking decision circuit configured to enable the data mask signal when the number of data bits having the first logic level is equal to or greater than a reference value, the reference value being greater than half of the first data size; and
a data inversion circuit configured to selectively invert data bits of each of the plurality of unit data in response to a flag signal and configured to provide input data to the write circuit.

8. The semiconductor memory device of claim 6, wherein the write circuit is configured to perform a masked write operation that does not write corresponding unit data of the input data to the memory cell array when the data mask signal is enabled, and the write circuit configured to perform a data write operation that writes corresponding unit data of the input data to the memory cell array when the data mask signal is disabled.

9. The semiconductor memory device of claim 6, wherein the flag signal indicates whether data bits of a corresponding one of the plurality of unit data are inverted or not.

10. The semiconductor memory device of claim 6, wherein the data masking decision circuit comprises:
a first operation circuit configured to operate on less significant data bits of the plurality of unit data to generate first output signals having a first pattern according to a number of data bits having the first logic level in the less significant data bits;
a second operation circuit configured to operate on more significant data bits of the plurality of unit data to generate second output signals having a second pattern according to a number of data bits having the first logic level in the more significant data bits; and
a data mask signal output circuit configured to provide the data mask signal based on the first output signals and the second output signals.

11. The semiconductor memory device of claim 6, wherein the data masking decision circuit comprises:
a first operation circuit configured to operate on less significant data bits of rest data bits to generate first output signals according to the number of data bits having the first logic level in the less significant data bits, the rest data bits being obtained by omitting at least two upper data bits from the plurality of unit data;
a second operation circuit configured to operate on more significant data bits of the rest data bits to generate second output signals according to the number of data bits having the first logic level in the more significant data bits; and
a data mask signal output circuits configured to provide the data mask signal based on the first output signals and the second output signals.

12. A memory system comprising:
a semiconductor memory device configured to perform a masked write operation according to a number of data bits having a first logic level in each of a plurality of unit data; and
a memory controller configured to provide a write data block including the plurality of unit data to the semiconductor memory device, the memory controller including
a memory interface configured to selectively convert some data bits having a second logic level to data bits having the first logic level in each of the plurality of unit data such that the number of data bits having the first logic level in each of the plurality of unit data is equal to or greater than a reference value, the reference value being greater than half of a data size of each of the plurality of unit data.

13. The memory system of claim 12, wherein the memory interface comprises:
a data inversion circuit configured to selectively invert each of the plurality of unit data to provide first output data and configured to generate a flag signal indicating whether each of the plurality of unit data is inverted or not; and
a bit converting circuit configured to selectively convert some data bits having the second logic level to the data bits having the first logic level in the first output data to provide second output data in response to a mask information signal, the mask information signal indicating whether a masked write operation is performed or not.

14. The memory system of claim 13, wherein the bit converting circuit converts some data bits having the second logic level to the data bits having the first logic level in the first output data such that a number of the first data bits in rest data bits is equal to or greater than the reference value when the mask information signal indicates that the masked write operation is to be performed, the rest data bits obtained by omitting at least two data bits from more significant data bits of the first output data.

15. The memory system of claim 12, wherein the semiconductor memory device comprises:
a data inversion/mask interface configured to receive the write data block and configured to selectively enable a data mask signal associated with each of the plurality of unit data having a first data size, based on the number of data bits having the first logic level in a second data size of each of the plurality of unit data, the second data size being smaller than the first data size.

16. A memory system comprising:
a memory controller configured to provide a write data block and a flag signal, the memory controller including,
a data inversion circuit configured to provide an output data block by selectively inverting each unit data of an input data block based on a number of data bits having a first logic level in each unit data of the input data block; and
a bit converting circuit configured to selectively convert some data bits having a second logic level to data bits having the first logic level in each unit data of the output data block to produce the write data block, the data inversion circuit selectively converting the output data block in response to a mask information signal such that the number of data bits having a first logic level in each unit data of the write data block is equal to or greater than a reference value, and
a semiconductor memory device configured to perform one of a masked write operation and a write operation based on the number of data bits having the first logic level in the write data block.

17. The memory system of claim 16, wherein the reference value is greater than half of a data size of each unit data of the output data block and is smaller than a data size of each unit data of the output data block.

18. The memory system of claim 16, wherein the data inversion circuit is further configured to provide the flag signal indicating whether corresponding unit data of the write data block is inverted or not.

19. The memory system of claim 16, wherein the data inversion circuit is configured to count a number of bit changes between a unit data of the write data block and a unit data of a previous write data block immediately preceding the write data block, and is configured to selectively invert data bits of the unit data of the write data block based on the number of bit changes.

20. The memory system of claim 16, wherein the bit converting circuit is configured to selectively convert two data bits having the second logic level to data bits having the first logic level in the unit data of the output data block when the mask information signal is one of a high logic level and a low logic level.
